(19) United States
(12) Patent Application Publication
(10) Pub. No.: US 2013/0083507 A1
(43) Pub. Date: Apr. 4, 2013

(54) Display Holder Assembly

(71) Applicant: Edward G. Guirlinger, New Albany, OH (US)

(72) Inventor: Edward G. Guirlinger, New Albany, OH (US)

(21) Appl. No.: 13/249,133

(22) Filed: Sep. 29, 2011

(51) Int. Cl. H05K 7/02; H05K 7/00; B62D 25/14; F16M 13/00; F16B 47/00

(52) U.S. Cl. 361/809; 248/309.1; 248/205.3; 296/70

(57) ABSTRACT

A device holder assembly is disclosed for securing an electronic device to a stable surface. In one embodiment, the device holder assembly comprises a base component and a device component. The device component is movable between a disengaged position in which the base component and the device component are not in contact with one another, and an engaged position in which a mating protuberance of the base component cooperates with an axial aperture formed by the device component.

### TECHNICAL FIELD

The present application generally relates to devices and methods for removably mounting small electronic devices to a stable surface. More specifically, the present application relates to a device holder having mating components.

### BACKGROUND

Holders for small electronic devices such as mobile telephones, MP3 players, PDAs and portable GPS units, hereinafter referred to collectively as devices, are well known in the art. Some device holders secure devices to belts while other device holders secure devices to other objects, such as dashboards or windshields. Many device holders are designed specifically according to the shape and dimensions of a specific device, making such device holders unsuitable for general use or use with any other device.

Other device holders are designed to accommodate devices of varying size, but the mechanical components that enable adjustment of size and/or shape are bulky and may impede functionality or limit placement of a device. A need therefore exists for a device holder which can accommodate a wide variety of devices. Additionally, a need exists for a device holder that does not impede operation of a device being held. Further, a need exists for a device holder which is compact, allowing it to be mounted in a wide variety of environments.

### SUMMARY

According to a first aspect of the present application, a first example device holder assembly is disclosed. The first example device holder assembly comprises a base component and a device component. The base component comprises a base mounting surface for attaching the base component to a stable surface, and a mating protuberance. The device component comprises a device mounting surface for attaching the device component to a device. The device component forms an axial aperture configured to mate with mating protuberance of the base component.

The device component is moveable with respect to the base component between a disengaged position and an engaged position. In the disengaged position, the base component and the device component are not in contact with one another. In the engaged position, the mating protuberance of the base component cooperates with the axial aperture formed by the device component to maintain the relative position of the base component and the device component.

According to a second aspect of the present application, an example electronic device assembly is disclosed. The example electronic device assembly comprises a base component and an electronic device case. The base component comprises a base mounting surface for attaching the base component to a surface, and a mating protuberance. The electronic device case forms an axial aperture configured to mate with mating protuberance of the base component.

The electronic device case is moveable with respect to the base component between a disengaged position and an engaged position. In the disengaged position, the electronic device case and the base component are not touching. In the engaged position, the mating protuberance cooperates with the electronic device case.

According to a third aspect of the present application, an example vehicle dashboard assembly is disclosed. The vehicle dashboard assembly comprises a vehicle dashboard and a device component. The vehicle dashboard comprises a mating protuberance, and a device component comprises a device mounting surface for attaching the device component to a device. The device component forms an axial aperture configured to mate with mating protuberance of the vehicle dashboard.

The device component is moveable with respect to the vehicle dashboard between a disengaged position and an engaged position. In the disengaged position, the vehicle dashboard and the device component are not in contact with one another. In the engaged position, the mating protuberance of the vehicle dashboard cooperates with the axial aperture formed by the device component to maintain the relative position of the vehicle dashboard and the device component.

According to a fourth aspect of the present application, an example display monitor assembly is disclosed. The display monitor assembly comprises a display monitor and a device component. The display monitor comprises a mating protuberance, and a device component comprises a device mounting surface for attaching the device component to a device. The device component forms an axial aperture configured to mate with mating protuberance of the display monitor.

The device component is moveable with respect to the display monitor between a disengaged position and an engaged position. In the disengaged position, the display monitor and the device component are not in contact with one another. In the engaged position, the mating protuberance of the display monitor cooperates with the axial aperture formed by the device component to maintain the relative position of the display monitor and the device component.

### BRIEF DESCRIPTION OF THE DRAWINGS

The accompanying figures, which are incorporated in and constitute a part of the specification, illustrate various example apparatuses, systems, methods, and so on, and are used merely to illustrate various example embodiments. It should be noted that various components depicted in the figures may not be drawn to scale, and that the various assemblies and designs depicted in the figures are presented for purposes of illustration only, and should not be considered in any way as limiting.

FIG. 1A illustrates an exploded perspective view of an example device holder assembly.

FIG. 1B illustrates a perspective view of the example device holder assembly of FIG. 1A.

FIG. 2A illustrates a front perspective view of base component 200.

FIG. 2B illustrates a rear perspective view of base component 200.

FIG. 2C illustrates a left side view of base component 200.

FIG. 3A illustrates a front perspective view of device component 300.

FIG. 3B illustrates a rear perspective view of device component 300.

FIG. 4 illustrates a vehicle dashboard comprising an integrated mating protuberance.

FIG. 5 illustrates an electronic device comprising an axial aperture.

FIG. 6 illustrates a laptop computer monitor comprising an integrated mating protuberance.

### DRAWING REFERENCE NUMERALS

The following reference characters identify the associated elements depicted in the drawings describing the present invention:

| | | | |
|---|---|---|---|
| 100 | Example device holder assembly | 300 | Device element |
| 200 | Base element | 310 | Device mounting surface |
| 210 | Base mounting surface | 320 | Flange |
| 220 | Mating protuberance | 322 | Axial aperture |
| 222 | Lip | 324 | Tapered base receiving surface |
| 224 | Tapered portion | 400 | Vehicle dashboard |
| 226 | Beveled portion | 500 | Electronic device |
| 230 | Support structure | 600 | Laptop computer monitor |

### DETAILED DESCRIPTION

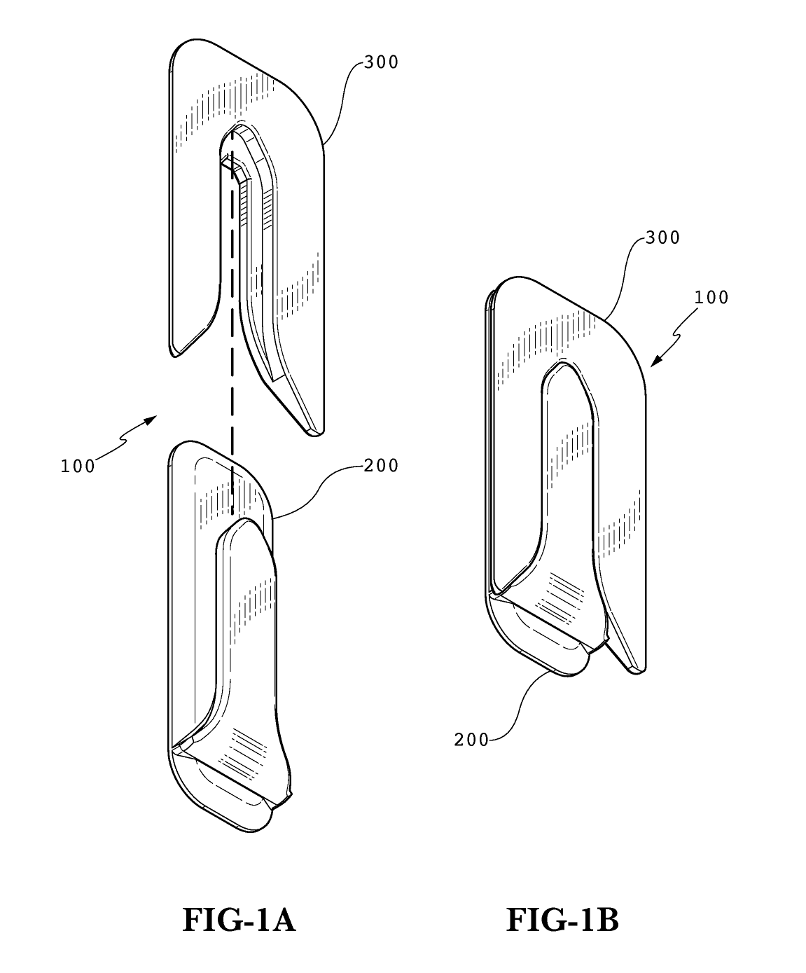

FIGS. 1A and 1B illustrate an example device holder assembly 100. FIG. 1A is an exploded perspective view of example device holder assembly 100. FIG. 1B is a perspective view of example device holder assembly 100 in an engaged configuration.

Assembly 100 holds or mounts a small electronic device, to the surface of another object. As illustrated in FIGS. 1A and 1B, device holder assembly 100 comprises a base component 200 and a device component 300. Base component 200 may be attached to a stable surface or object such as a vehicle dashboard, a display monitor, a wall, a desk, a counter, or a refrigerator, for example. Device component 300 may be attached to a relatively small electronic or other device, such as a GPS unit, an MP3 player, or a mobile telephone, for example.

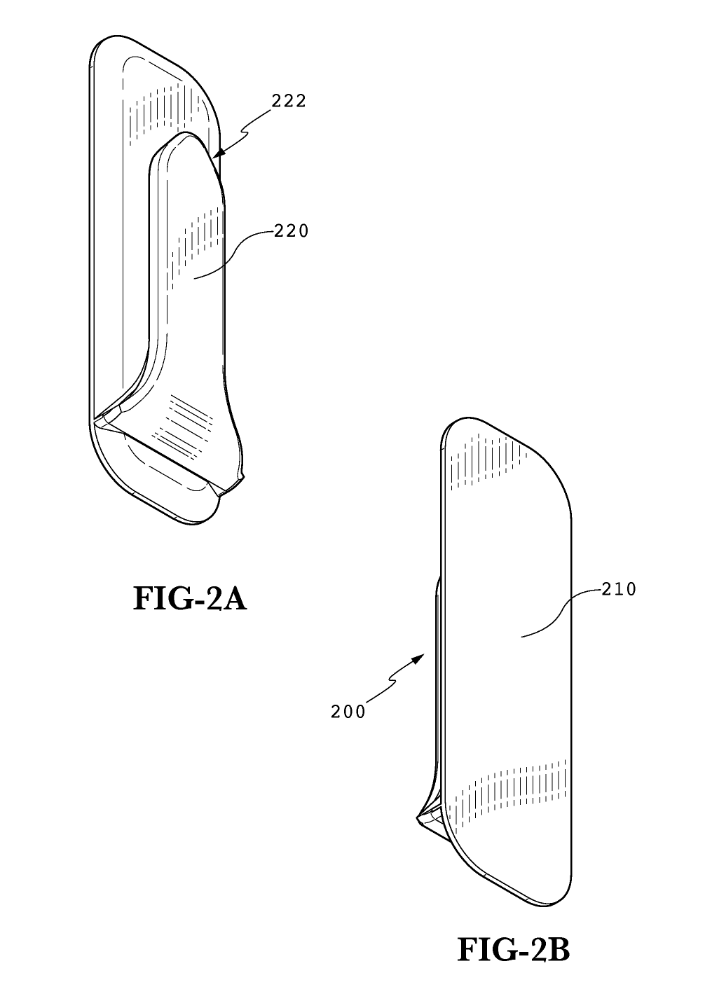

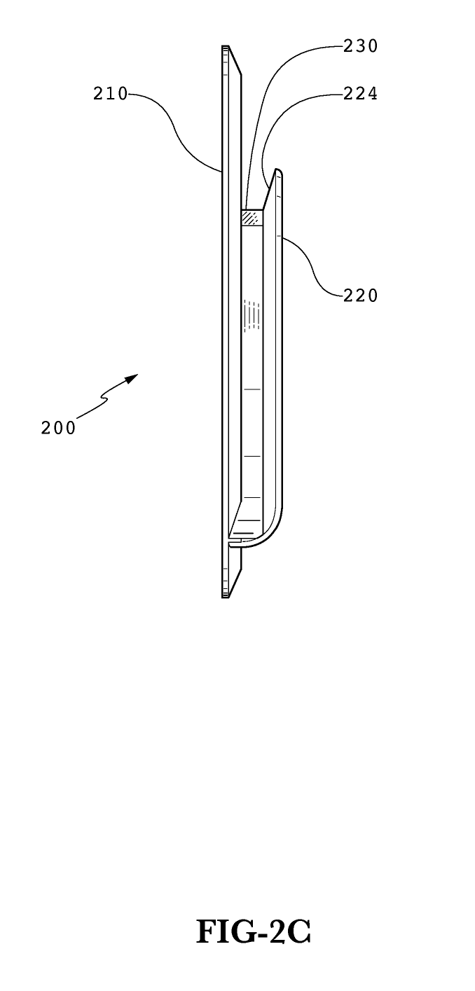

Referring now to FIGS. 2A and 2B, the base component 200 of assembly 100 is illustrated. Base component 200 comprises a mounting surface 210 which cooperates with an object to which a device is to be secured, and a mating protuberance 220 which cooperates with the device component 300 to hold a device to the surface of an object. The base mounting surface 210 may comprise an adhesive for securing the base component 200 to the object. In one embodiment, the adhesive may be applied directly to the mounting surface 210. In an alternate embodiment, the adhesive may be integrated into double-sided tape applied to the mounting surface 210.

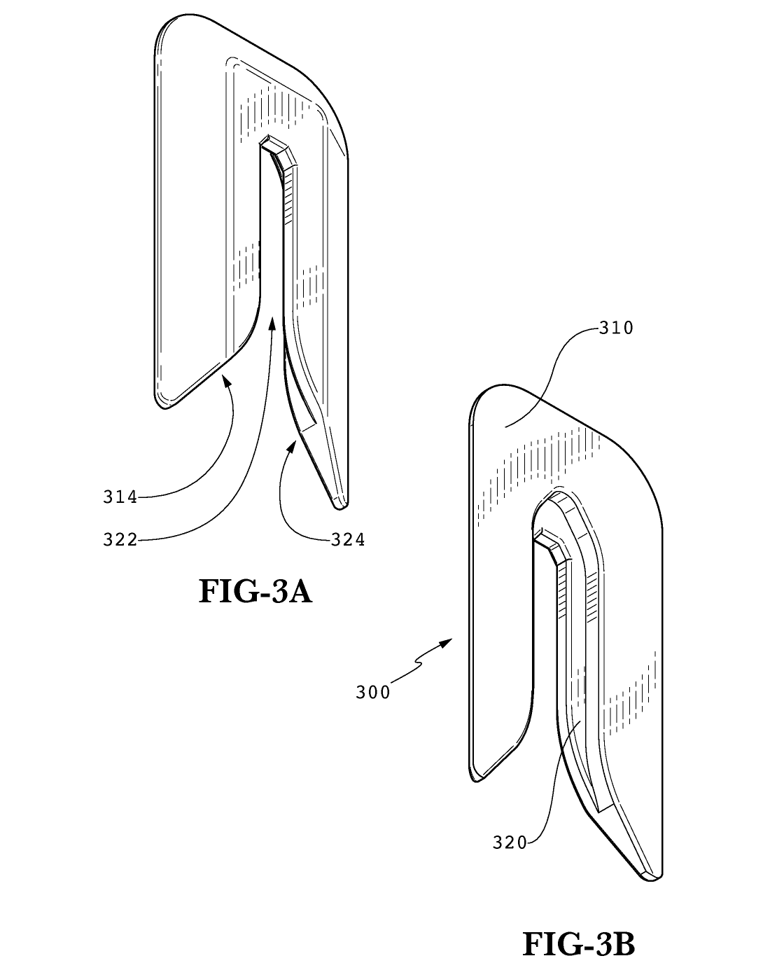

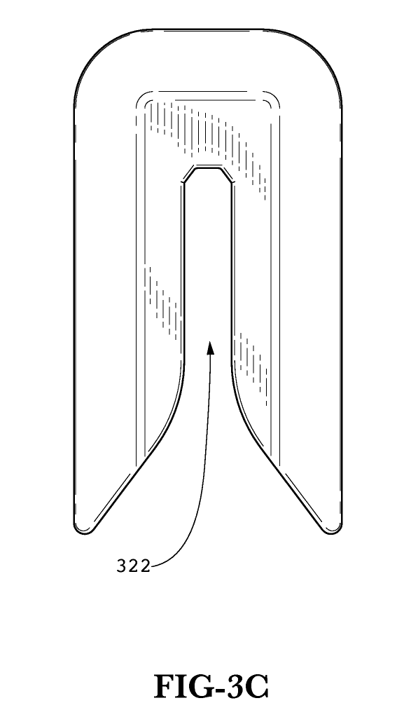

Mating protuberance 220 is configured to cooperate with device component 300. Mating protuberance 220 comprises a lip 222 which mates with an axial aperture 320 of device component 300 as described in more detail below with reference to FIGS. 3A-3C. Mating protuberance 220 further comprises a tapered portion 224 and a beveled portion 226 which advantageously accommodate mating of base component 200 and device component 300. Tapered portion 224 acts as a guide to assist with lateral alignment of the lip 220 with the device component 300. Beveled portion 226 acts as a guide to assist with depth alignment of the lip 220 with the device component 300.

Example base component 200 further comprises a support structure 230 which supports lip 220. Support structure 230 prevents breakage of base component 200. Without support structure 230, base component 200 would form a hook or a tab which could be easily broken or bent. It should be recognized that while the support structure provides advantageous benefits, it is not necessary for the operation of a device holder assembly.

Referring now to FIGS. 3A-3C, the features of example device component 300 are illustrated. Device component 300 comprises a device mounting surface 310 which cooperates with a device to be secured. The device mounting surface 310 may comprise an adhesive for securing the device component 300 to the device. In one embodiment, the adhesive may be applied directly to the mounting surface 310. In an alternate embodiment, the adhesive may be integrated into double-sided tape applied to the device mounting surface 310.

Device component 300 forms a flange 320 and an axial aperture 322 which cooperate with lip 222 and support structure 230 of mating protuberance 220 of the base component 200 when assembly 100 is configured in an engaged configuration as illustrated in FIG. 1B. The axial aperture 322 receives and cooperates with mating protuberance 220 of the base component 200, and a portion of axial aperture 322 is defined by a tapered base receiving portion 324 which acts as a guide to assist with lateral alignment of mating protuberance 220 with the device component 300. Axial aperture 322, particularly the portion of axial aperture 322 formed by the device mounting surface 310, provides a path for base component 200 that is free of obstructions.

In the illustrated embodiment, the axial aperture is a vertical elongated slot. The axial aperture of the illustrated embodiment provides significant surface area contact between the mating protuberance 220 and the device component 300. The surface area contact provides stability of the device when it is in the engaged configuration.

Although not shown, base component 220 and/or device component 300 may comprise one or more retention elements for maintaining the relative position of the base component 200 and device component 300 with respect to each other when the assembly is configured in the engaged configuration. In one embodiment, the retention elements may be contiguous nubs or bumps integrated into the base component 200 and the device component 300. In another embodiment, the retention elements may be nubs or bumps integrated into one of the base component 200 or the device component 300 and corresponding indentations in the other component.

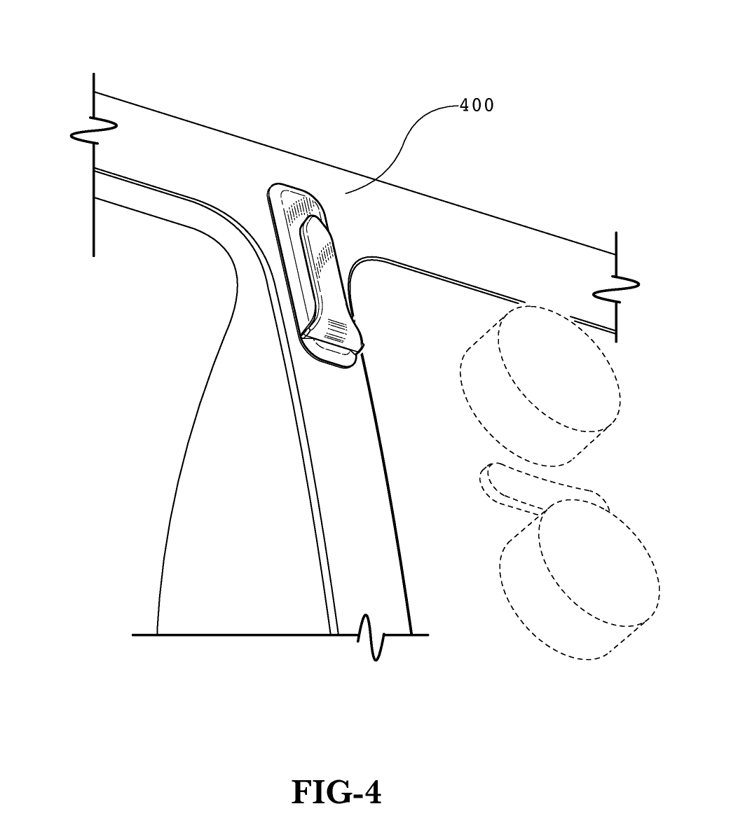

In an alternate embodiment, a base component may be integrated into an object to which a device may be secured. For example, a vehicle dashboard, display monitor, cabinet or other object may be manufactured to physically define a base component to enable a mobile telephone or other device comprising mating component 300 to be secured. In such an alternate embodiments, the base component would not comprise a base mounting surface. FIG. 4 illustrates a vehicle dashboard 400 comprising a mating aperture as set forth in the present application. FIG. 6 illustrates an example monitor 600, specifically a laptop monitor, comprising a mating aperture as set forth in the present application.

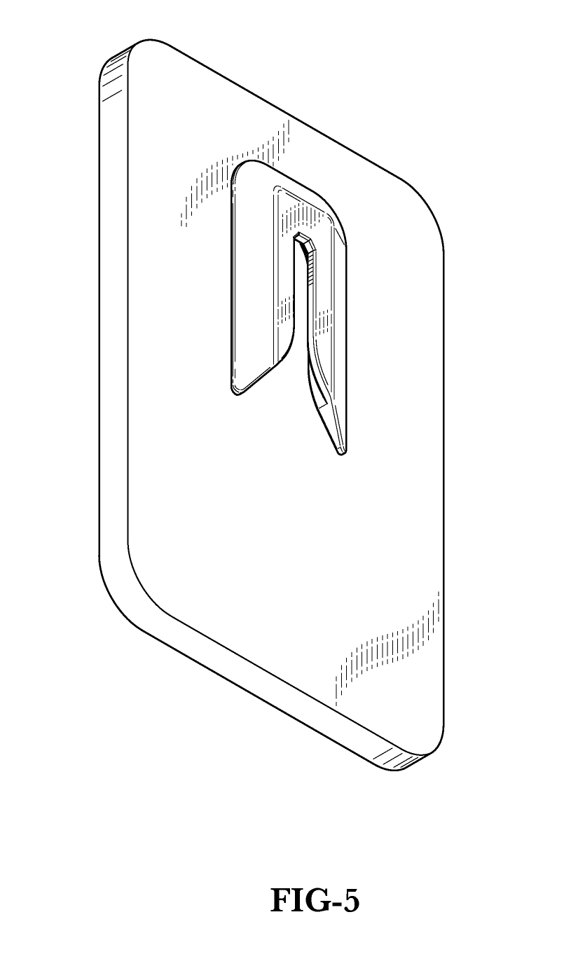

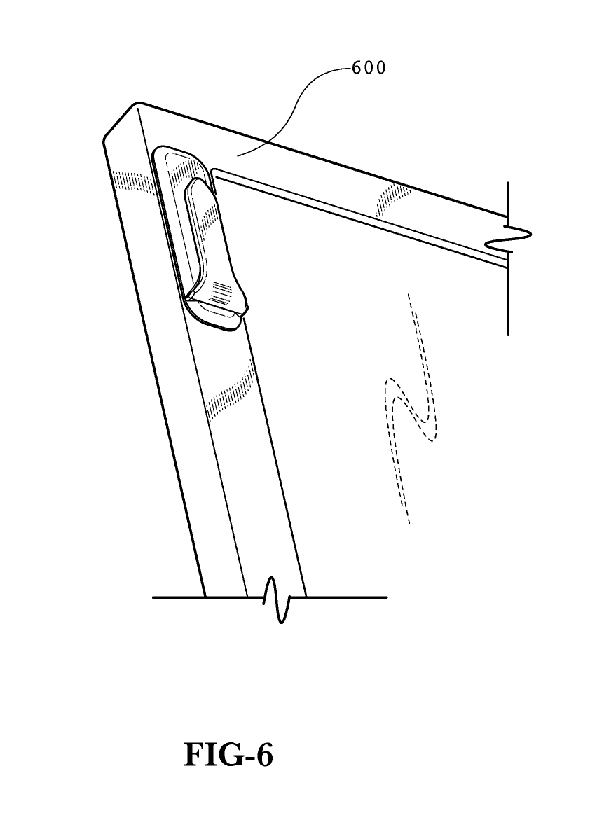

In another alternate embodiment, a device component may be integrated into the casing of a device to be secured using a base component. For example, a GPS unit, mobile telephone, handheld remote controller, MP3 player, or PDA or other device may be manufactured to physically define a device component to enable the device to be secured to a base component. In such an alternate embodiment, the device component would not comprise a device mounting surface. FIG. 5 illustrates an example portable electronic device 500, specifically an Apple brand iPhone, comprising an axial aperture as set forth in the present application.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

Furthermore, while the devices, systems, methods, and so on have been illustrated by describing examples, and while the examples have been described in considerable detail, it is not the intention of the applicant to restrict, or in any way, limit the scope of the appended claims to such detail. It is, of course, not possible to describe every conceivable combination of components or methodologies for purposes of describing the devices, systems, methods, and so on provided herein. Additional advantages and modifications will readily appear to those skilled in the art. Therefore, the invention, in its broader aspects, is not limited to the specific details and illustrative examples shown and described. Accordingly, departures may be made from such details without departing from the spirit or scope of the applicant's general inventive concept. Thus, this application is intended to embrace alterations, modifications, and variations that fall within the scope of the appended claims. The preceding description is not meant to limit the scope of the invention. Rather, the scope of the invention is to be determined by the appended claims and their equivalents.

Finally, to the extent that the term “includes” or “including” is employed in the detailed description or the claims, it is intended to be inclusive in a manner similar to the term “comprising,” as that term is interpreted when employed as a transitional word in a claim. Furthermore, to the extent that the term “or” is employed in the claims (e.g., A or B) it is intended to mean “A or B or both.” When the applicants intend to indicate “only A or B, but not both,” then the term “only A or B but not both” will be employed. Similarly, when the applicants intend to indicate “one and only one” of A, B, or C, the applicants will employ the phrase “one and only one.” Thus, use of the term “or” herein is the inclusive, and not the exclusive use. See Bryan A. Garner, A Dictionary of Modern Legal Usage 624 (2d. Ed. 1995).

What is claimed is:

1. A device holder assembly comprising:
a base component, the base component comprising:
a base mounting surface for attaching the base component to a surface, and
a mating protuberance; and
a device component, the device component comprising a device mounting surface for attaching the device component to a device, and the device component forming an axial aperture configured to mate with mating protuberance of the base component;
whereby the device component is moveable with respect to the base component between a disengaged position in which the base component and the device component are not in contact with one another, and an engaged position in which the mating protuberance of the base component cooperates with the axial aperture formed by the device component.

2. The device holder assembly of claim 1 wherein the base mounting surface comprises an adhesive surface.

3. The device holder assembly of claim 1 wherein the device mounting surface comprises an adhesive surface.

4. The device holder assembly of claim 1 wherein the mating protuberance comprises a lip.

5. The device holder assembly of claim 4 wherein the lip defines a tapered portion of the base component.

6. The device holder assembly of claim 4 wherein at least a portion of the lip is beveled.

7. The device holder assembly of claim 1 wherein at least a portion of the axial aperture is tapered.

8. The device holder assembly of claim 1 further comprising:
a first retention element formed by the device component; and
a second retention element formed within the mating protuberance;
whereby the first retention element cooperates with the second retention element to maintain the relative position of the base component and the device component when the device holder assembly is in the engaged configuration.

9. An electronic device assembly comprising:
a base component, the base component comprising:
a base mounting surface for attaching the base component to a surface, and
a mating protuberance; and
an electronic device case forming an axial aperture configured to mate with mating protuberance of the base component;
whereby the electronic device case is moveable with respect to the base component between a disengaged position in which the electronic device case and the base component are not touching, and an engaged position in which the mating protuberance cooperates with the electronic device case.

10. The electronic device assembly of claim 9 wherein the base mounting surface comprises an adhesive surface.

11. The electronic device assembly of claim 9 wherein the mating protuberance comprises a lip.

12. The electronic device assembly of claim 11 wherein the lip defines a tapered portion of the base component.

13. The electronic device assembly of claim 11 wherein at least a portion of the lip is beveled.

14. The electronic device assembly of claim 9 wherein at least a portion of the axial aperture is tapered.

15. The electronic device assembly of claim 9 further comprising:
a first retention element formed by the electronic device case; and
a second retention element formed within the mating protuberance;
whereby the first retention element cooperates with the second retention element to maintain the relative position of the base component and the electronic device case when the electronic device assembly is in the engaged configuration.

16. A vehicle dashboard assembly comprising:
a vehicle dashboard comprising a mating protuberance; and
a device component, the device component comprising a device mounting surface for attaching the device component to a device, and the device component forming an axial aperture configured to mate with mating protuberance of the vehicle dashboard;
whereby the device component is moveable with respect to the vehicle dashboard between a disengaged position in which the vehicle dashboard and the device component are not in contact with one another, and an engaged position in which the mating protuberance of the vehicle dashboard component cooperates with the axial aperture formed by the device component.

17. The vehicle dashboard assembly of claim 16 further comprising:
a first retention element formed by the device component; and
a second retention element formed within the mating protuberance;
whereby the first retention element cooperates with the second retention element to maintain the relative position of the vehicle dashboard and the device component when the vehicle dashboard assembly is in the engaged configuration.

18. A display monitor assembly comprising:
a display monitor comprising a mating protuberance; and
a device component, the device component comprising a device mounting surface for attaching the device component to a device, and the device component forming an axial aperture configured to mate with mating protuberance of the display monitor;
whereby the device component is moveable with respect to the display monitor between a disengaged position in which the display monitor and the device component are not in contact with one another, and an engaged position in which the mating protuberance of the display monitor component cooperates with the axial aperture formed by the device component.

19. The display monitor assembly of claim 18 further comprising:
a first retention element formed by the device component; and
a second retention element formed within the mating protuberance;
whereby the first retention element cooperates with the second retention element to maintain the relative position of the display monitor and the device component when the display monitor assembly is in the engaged configuration.
